(19) United States
(12) Patent Application Publication
(10) Pub. No.: US 2008/0265438 A1
(43) Pub. Date: Oct. 30, 2008

(54) LIQUID EPOXY RESIN COMPOSITION AND SEMICONDUCTOR DEVICE

(75) Inventor: Masatoshi ASANO, Annaka-shi (JP)

Correspondence Address: BIRCH STEWART KOLASCH & BIRCH, PO BOX 747, FALLS CHURCH, VA, 22040-0747, US

(73) Assignee: SHIN-ETSU CHEMICAL CO., LTD., Tokyo (JP)

(21) Appl. No.: 12/109,163

(22) Filed: Apr. 24, 2008

(30) Foreign Application Priority Data
Apr. 27, 2007 (JP) 2007-118607

(51) Int. Cl. H01L 23/16; C08L 63/00; C08K 3/36

(52) U.S. Cl. 257/778; 523/400; 523/216; 257/E23.135

(57) ABSTRACT

A liquid epoxy resin composition comprising (A) a liquid epoxy resin, (B) a curing agent, (C) an inorganic filler, (D) a hygroscopic agent, and optionally, (E) a fluxing agent has the advantages of void-free fill, shelf stability and solder connection, and is thus advantageously used in the fabrication of flip chip semiconductor devices by the no-flow method.

### CROSS-REFERENCE TO RELATED APPLICATION

This non-provisional application claims priority under 35 U.S.C. §119(a) on Patent Application No. 2007-118607 filed in Japan on Apr. 27, 2007, the entire contents of which are hereby incorporated by reference.

### TECHNICAL FIELD

This invention relates to liquid epoxy resin compositions for use as no-flow underfill which are void-free, reliable and effectively workable, and facilitate the process of fabricating semiconductor devices, especially flip chip semiconductor devices, and flip chip semiconductor devices encapsulated with the epoxy resin compositions.

### BACKGROUND ART

To meet the modern demand for further reducing the size, profile and weight of semiconductor packages, a significant increase in the density of semiconductor chips has been achieved. A typical technique of mounting high density semiconductor chips is flip-chip mounting which is on wide-spread use. A typical flip-chip mounting technique is the controlled collapse chip connection (4C) process of forming direct solder connections between solder electrodes on a semiconductor chip and solder bumps or lands on a circuit substrate. In this process, after solder bonding, the gap between the semiconductor chip and the circuit substrate is sealed with an epoxy resin underfill for the protection of solder connections.

In the prior art, the flip-chip mounting by C4 process entails resin encapsulation by the capillary flow method. The process includes a number of steps, (1) treatment with a flux for improving solder wetting, (2) solder connection, (3) flux cleaning, (4) infiltration of liquid sealing resin by a capillary action, and (5) resin curing. It takes a time for the resin to infiltrate in place. Thus the process suffers from a low productivity. Additionally, the flux removal by cleaning becomes inefficient as the width of and the pitch between solder electrodes are reduced. The flux residue can interfere with wetting of the sealing resin, and ionic impurities in the flux residue detract from the reliability of semiconductor packages. Many technical problems remain unsolved in association with the flux.

One countermeasure to the problems associated with the capillary flow method is a no-flow method involving directly applying a sealing resin compound having a flux component incorporated therein onto a circuit substrate, resting a semiconductor chip having solder electrodes thereon, and effecting reflow to achieve solder connection and resin sealing simultaneously as disclosed in Pennisi et al., U.S. Pat. No. 5,128,746, which is incorporated herein by reference. At the present, an attempt is made for increased productivity wherein an encapsulating resin having a flux function is coated onto a substrate using a flip chip bonder, a semiconductor chip having solder electrodes is rested thereon, and the assembly is heated and compressed for thereby simultaneously achieving solder connections between the substrate and the semiconductor chip and curing of the encapsulating resin within a brief time. However, since the heating operation for pressure bonding between the substrate and the semiconductor chip and curing the resin is conducted within a brief time, and since bonding of lead-free solder materials is conducted at higher temperatures than in the prior art, the problem of voids generated in the encapsulating resin becomes significant.

Voids are generated by the following main factors: (1) volatile matter in raw material components, (2) water generated when solder metal oxides are reduced by the action of flux, (3) voids entrained due to short wetting of the substrate with the encapsulating resin, and (4) moisture absorbed by the substrate.

Solutions to (1) include use of more curable resins (JP-A 2005-154564) and optimization of resin curing conditions and bonding conditions of the flip chip bonder (JP-A 2005-183453). One exemplary solution to (3) is incorporation of a leveling agent (JP-A 2004-67930). No effective solution to (2) has been identified. The inventor has found that (2) causes relatively outstanding void generation and thus, finding a solution to (2) is the key requisite to overcome the void problem. Understandably, a simple solution to (4) is by drying the substrate.

### DISCLOSURE OF THE INVENTION

An object of the invention is to provide a liquid epoxy resin composition for use as no-flow underfill and for flip chip semiconductor encapsulation, which is shelf stable and void-free while insuring solder connection and adhesion; and a flip chip semiconductor device encapsulated with the epoxy resin composition.

The inventor has found that incorporation of a hygroscopic agent in an epoxy resin composition for use as no-flow underfill results in an epoxy resin composition for semiconductor encapsulation meeting a commercially viable combination of void-free fill, solder connection, and reliability.

In one aspect, the invention provides a liquid epoxy resin composition for use as no-flow underfill comprising

(A) a liquid epoxy resin,

(B) a curing agent,

(C) an inorganic filler, and

(D) a hygroscopic agent.

In a preferred embodiment, the composition may further comprise (E) a fluxing agent. The preferred hygroscopic agent (D) is a molecular sieve and/or a spherical porous silica having a specific surface area of 100 to 500 m²/g.

Also provided are a liquid epoxy resin composition for flip chip semiconductor encapsulation, comprising the liquid epoxy resin composition for use as no-flow underfill, and a flip chip semiconductor device encapsulated with the liquid epoxy resin composition in the cured state.

### BENEFITS OF THE INVENTION

The liquid epoxy resin composition for use as no-flow underfill according to the invention is improved in working efficiency, void-free fill, solder connection, and adhesion, and thus advantageously used in the fabrication of flip chip semiconductor devices by the no-flow method featuring a high productivity. This ensures that highly reliable semiconductor devices are fabricated.

### BRIEF DESCRIPTION OF THE DRAWINGS

FIG. 1 is a schematic cross-section of a flip chip semiconductor device according to one embodiment of the invention.

### DESCRIPTION OF THE PREFERRED EMBODIMENT

Briefly stated, the liquid epoxy resin composition for use as no-flow underfill according to the invention comprises (A) a liquid epoxy resin, (B) a curing agent, (C) an inorganic filler, and (D) a hygroscopic agent as essential components. A fluxing agent is also incorporated as an essential component when the fluxing function the curing agent possesses in itself is weak.

### A. Liquid Epoxy Resin

The epoxy resin used herein may be any of well-known epoxy resins as long as they have at least two epoxy groups per molecule and are liquid at room temperature (25° C.). Exemplary epoxy resins include bisphenol A epoxy resins, bisphenol AD epoxy resins, bisphenol F epoxy resins, naphthalene epoxy resins, phenol novolac epoxy resins, biphenyl epoxy resins, glycidyl amine epoxy resins, alicyclic epoxy resins, and dicyclopentadiene epoxy resins. Inter alia, the bisphenol A epoxy resins, bisphenol F epoxy resins, bisphenol AD epoxy resins, and naphthalene epoxy resins are preferred for heat resistance and moisture resistance.

Note that epoxy resins contain a minor amount of chlorine derived from epichlorohydrin used in their synthesis. It is preferred that the epoxy resin have a total chlorine content equal to or less than 1,500 ppm, and more preferably equal to or less than 1,000 ppm. Also preferably the epoxy resin exhibits a chlorine-in-water concentration of not more than 10 ppm after the epoxy resin is combined with an equal weight of deionized water and held at 100° C. for 20 hours for extraction. The epoxy resins described above may be used alone or in admixture.

### B. Curing Agent

The curing agent used herein may be any of well-known agents and is not particularly limited. Suitable curing agents include amine compounds, phenol compounds, acid anhydrides, and carboxylic acids. Inter alia, aromatic amines, phenol compounds, and acid anhydrides are preferably used for adhesion and reliability in an environmental test. These curing agents may be used alone or in admixture. When a mixture of two or more curing agents is used, however, it is desired to avoid a combination of an acidic compound and a basic compound because this combination adversely affects shelf stability. From the working standpoint requiring that the epoxy resin composition of the invention properly flow at room temperature, it is desirable to use a curing agent which is liquid at 25° C. When a curing agent which is solid at 25° C. is used, it should preferably be dissolved in another curing agent which is liquid at 25° C. so that the overall curing agent is liquid.

The aromatic amine curing agent used herein is not particularly limited as long as it has at least two amino (—NH₂) groups in the molecule. Preferred aromatic amines include 3,3′-diethyl-4,4′-diaminodiphenylmethane, 3,3′,5,5′-tetramethyl-4,4′-diaminodiphenylmethane, 3,3′, 5,5′-tetraethyl-4,4′-diaminodiphenylmethane, 2,4-diaminotoluene, 1,4-phenylenediamine, and 1,3-phenylenediamine.

The phenol compound used herein is not particularly limited as long as it has at least two hydroxyl groups in the molecule. Exemplary phenol compounds include cresol novolac resins, phenol novolac resins, dicyclopentadiene ring phenol resins, phenol aralkyl resins, and naphthol resins. Inter alia, phenol novolac resins are preferably used because of better adhesion. Exemplary preferred phenol compounds which are liquid at room temperature include allylated phenol novolac resins, diallylated bisphenol A, and diallylated bisphenol F.

The acid anhydride used herein is not particularly limited as long as it has an acid anhydride group in the molecule. A choice may be made among those acid anhydrides which are commonly used as the curing agent for epoxy resins. Exemplary preferred acid anhydrides include methyltetrahydrophthalic anhydride, methylhexahydrophthalic anhydride, hexahydrophthalic anhydride, methylhymic anhydride, pyromellitic dianhydride, maleic alloocimene, benzophenonetetracarboxylic dianhydride, 3,3′,4,4′-biphenyltetrabisbenzophenone tetracarboxylic dianhydride, (3,4-dicarboxyphenyl)ether dianhydride, bis(3,4-dicarboxyphenyl)methane dianhydride, 2,2-bis(3,4-dicarboxyphenyl)propane dianhydride, 3,4-dimethyl-6-(2-methyl-1-propenyl)-1,2,3,4-tetrahydro-phthalic anhydride, and 1-isopropyl-4-methyl-bicyclo-[2.2.2]oct-5-ene-2,3-dicarboxylic anhydride.

From the standpoints of cure and flow, the liquid epoxy resin and the curing agent are preferably combined such that 0.6 to 1.3 equivalents of active hydrogen groups in the curing agent are available per equivalent of epoxy groups in the epoxy resin. The more preferred proportion is to provide 0.8 to 1.1 equivalents of active hydrogen groups per equivalent of epoxy groups. The active hydrogen groups in the curing agent are amino (or imino) groups in the case of amine compounds, phenolic hydroxyl groups in the case of phenol compounds, carboxylic acid groups derived from acid anhydride groups in the case of acid anhydrides, and carboxylic acid groups in the case of carboxylic acids. Less than 0.6 equivalent of active hydrogen groups may provide under-cure or result in a poor profile of cured properties. If the amount of active hydrogen groups is more than 1.3 equivalents, some acid anhydride may be left unreacted, resulting in deteriorated adhesion properties and a cured resin having a lower glass transition temperature, which may lead to a substantial loss of thermal reliability.

### C. Inorganic Filler

To the epoxy resin composition of the invention, any of well-known inorganic fillers may be added in order to reduce the coefficient of expansion of the composition. Suitable inorganic fillers include fused silica, crystalline silica, alumina, titanium oxide, silica-titania, boron nitride, aluminum nitride, silicon nitride, magnesia, magnesium silicate, and aluminum, and may be used alone or in admixture. Inter alia, spherical fused silica is desirable for providing a lower viscosity. The spherical fused silica has an average particle size of 0.1 to 10 μm, preferably 0.1 to 5 μm and a maximum particle size equal to or less than 30 μm, preferably equal to or less than 20 μm.

As used herein, the “average particle size” and “maximum particle size” can be determined by a particle size distribution measuring instrument based on the laser light diffraction method. The “average particle size” is a weight average value D₅₀ (particle diameter when the cumulative weight reaches 50%, or median diameter) on particle size distribution measurement by the laser light diffraction method.

The inorganic filler may have previously been surface treated with coupling agents such as silane and titanate coupling agents in order to enhance the bond strength between the resin and the filler. Preferably such a surface treated inorganic filler is compounded in the composition. Preferred coupling agents used herein are silane coupling agents including epoxysilanes such as

γ-glycidoxypropyltrimethoxysilane,
γ-glycidoxypropylmethyldiethoxysilane, and
β-(3,4-epoxycyclohexyl)ethyltrimethoxysilane;
aminosilanes such as
N-β-(aminoethyl)-γ-aminopropyltrimethoxysilane,
γ-aminopropyltriethoxysilane,
N-phenyl-γ-aminopropyltrimethoxysilane; and
mercaptosilanes such as γ-mercaptosilane. The amount of the coupling agent and the surface treatment technique are not particularly limited.

An appropriate amount of the inorganic filler compounded is 50 to 900 parts, and more preferably 100 to 500 parts by weight per 100 parts by weight of the epoxy resin. Less than 50 pbw of the filler may lead to a greater coefficient of expansion and allow the cured composition to crack in a thermal cycling test. More than 900 pbw of the filler may have a likelihood of the composition building up a viscosity, generating voids, and interfering with solder connection.

### D. Hygroscopic Agent

The hygroscopic agent used herein is not particularly limited as long as it is an inorganic substance which is moisture absorptive and highly heat resistant. Exemplary hygroscopic agents include inorganic porous materials such as molecular sieves (zeolites), porous silica, active alumina and titania gel; calcined forms of layered double hydroxides, typically hydrotalcite; calcium oxide and magnesium oxide. Of these, molecular sieve and porous silica are preferred because of a good balance of moisture absorption, solder connection and flow. The amount of the hygroscopic agent compounded may vary with a particular type, and it is generally 1 to 200 parts by weight per 100 parts by weight of liquid epoxy resin (A) and curing agent (B) combined.

The molecular sieve used herein may be of any type except the hydrophobic type although preference is given to those molecular sieves of powder type consisting of zeolite crystals and free of clay binder. Since the molecular sieve is highly moisture absorptive in a high temperature range, it is fully effective for reducing voids, even in a relatively small amount. Then an appropriate amount of the molecular sieve is 1 to 30 parts, and more preferably 5 to 20 parts by weight per 100 parts by weight of liquid epoxy resin (A) and curing agent (B) combined. Less than 1 pbw of the molecular sieve may fail to achieve the void-reducing effect. More than 30 pbw of the molecular sieve may degrade solder connection or provide the epoxy resin composition with such a high viscosity as to interfere with working. The molecular sieve has an average particle size of 0.1 to 10 μm, preferably 0.1 to 5 μm and a maximum particle size equal to or less than 30 μm, preferably equal to or less than 20 μm.

The other preferred hygroscopic agent is porous silica which is in spherical form. Even when compounded in a large amount, porous silica is effective for inhibiting the epoxy resin composition from increasing its viscosity and thus achieves its void reducing effect fully without detracting from working efficiency. Preferably spherical porous silica has a specific surface area of 100 to 500 m²/g as measured by the BET method using nitrogen gas as the adsorbate and is compounded in an amount of 5 to 200 parts, and more preferably 10 to 100 parts by weight per 100 parts by weight of liquid epoxy resin (A) and curing agent (B) combined. With a specific surface area of less than 100 m²/g, no satisfactory void reducing effect may be achieved. With a specific surface area of more than 500 m²/g, the epoxy resin composition may have too high a viscosity to work with. Less than 5 pbw of the porous silica may fail to achieve the void-reducing effect. More than 200 pbw of the porous silica may degrade solder connection or provide the epoxy resin composition with such a high viscosity as to interfere with working. The porous silica has an average particle size of 0.1 to 10 μm, preferably 0.1 to 5 μm and a maximum particle size equal to or less than 30 μm, preferably equal to or less than 20 μm.

### E. Fluxing Agent

A fluxing agent is used herein to make up the fluxing capability of the curing agent when it is short. In general, many curing agents have a fluxing capability in themselves. Then, depending on the type and fluxing capability of a particular curing agent used, the use, type and amount of a fluxing agent are selected. Where the curing agents are phenol compounds, acid anhydrides, and carboxylic acids which have a high fluxing capability, a fluxing agent need not necessarily be added, but a fluxing agent may be compounded as long as it does not adversely affect the void-reducing effect. Where the curing agents are amine compounds, many of which have a relatively weak fluxing capability, it is desirable to add a fluxing agent.

The fluxing agent used herein is not particularly limited as long as it has a reducing capability. Suitable fluxing agents include hydrazides, amino acids, organic acids, phenols, reducing sugars, sulfides, and thio ether phenols.

Specifically, exemplary fluxing agents are given below. Exemplary hydrazides include 3-bis(hydrazinocarbonethyl)-5-isopropylhydantoin or 7,11-octadecadiene-1,18-dicarbohydrazide, adipic dihydrazide, sebacic dihydrazide, dodecanedioic hydrazide, isophthalic dihydrazide, propionic hydrazide, salicylic hydrazide, 3-hydroxy-2-naphthoic hydrazide, and benzophenone hydrazone.

Exemplary amino acids include isoleucine, glycine, alanine, serine, lysine, proline, arginine, aspartic acid, glutamine, glutamic acid, and aminobenzoic acid.

Suitable organic acids includes aliphatic monocarboxylic acids such as caproic acid, enanthic acid, caprylic acid, capric acid, undecanoic acid, tridecanoic acid, myristic acid, pentadecanoic acid, palmitic acid, heptadecanoic acid, nonadecanoic acid, arachidic acid, isocaprylic acid, propylvaleric acid, ethylcaproic acid, isocapric acid, 2,2-dimethylbutanoic acid, 2,2-dimethylpentanoic acid, 2,2-dimethylhexanoic acid, 2,2-dimethyloctanoic acid, 2-methyl-2-ethylbutanoic acid, 2-methyl-2-ethylpentanoic acid, 2-methyl-2-ethylhexanoic acid, 2-methyl-2-ethylheptanoic acid, 2-methyl-2-propyl-pentanoic acid, 2-methyl-2-propylhexanoic acid, 2-methyl-2-propylheptanoic acid, octylic acid, octenoic acid, oleic acid, cyclopentanecarboxylic acid, and cyclohexanecarboxylic acid; aliphatic polycarboxylic acids such as oxalic acid, malonic acid, succinic acid, glutaric acid, adipic acid, pimelic acid, suberic acid, azelaic acid, sebacic acid, methylmalonic acid, ethylmalonic acid, methylsuccinic acid, ethylsuccinic acid, 2,2-dimethylsuccinic acid, 2,3-dimethylsuccinic acid, 2-methylglutaric acid, 3-methylglutaric acid, maleic acid, citraconic acid, itaconic acid, methyleneglutaric acid, monomethyl maleate, 1,5-octanedicarboxylic acid, 5,6-decanedicarboxylic acid, 1,7-decanedicarboxylic acid, 4,6-dimethyl-4-nonene-1,2-dicarboxylic acid, 4,6-dimethyl-1,2-nonanedicarboxylic acid, 1,7-dodecanedicarboxylic acid, 5-ethyl-1,10-decanedicarboxylic acid, 6-methyl-6-dodecene-1,12-dicarboxylic acid, 6-methyl-1,12-dodecanedicarboxylic acid, 6-ethylene-1,12-dodecanedicarboxylic acid, 6-ethyl-1,12-dodecanedicarboxylic acid, 7-methyl-7-tetradecene-1,14-dicarboxylic acid, 7-methyl-1,14-tetradecanedicarboxylic acid, 3-hexyl-4-decene-1,2-dicarboxylic acid, 3-hexyl-1,2-decanedicarboxylic acid, 6-ethylene-9-hexadecene-1,16-dicarboxylic acid, 6-ethyl-1,16-hexadecanedicarboxylic acid, 6-phenyl-1,12-dodecanedicarboxylic acid, 7,12-dimethyl-7,11-octadecadiene-1,18-dicarboxylic acid, 7,12-dimethyl-1,18-octadecanedicarboxylic acid, 6,8-diphenyl-1,14-tetradecanedicarboxylic acid, 1,1-cyclopentanedicarboxylic acid, 1,2-cyclopentanedicarboxylic acid, 1,1-cyclohexenedicarboxylic acid, 1,2-cyclohexenedicarboxylic acid, 4-cyclohexene-1,2-dicarboxylic acid, 5-norbornene-2,3-dicarboxylic acid, and malic acid; aromatic monocarboxylic acids such as benzoic acid, toluic acid, ethylbenzoic acid, propylbenzoic acid, isopropylbenzoic acid, butylbenzoic acid, isobutylbenzoic acid, hydroxybenzoic acid, anisic acid, ethoxybenzoic acid, propoxybenzoic acid, isopropoxybenzoic acid, butoxybenzoic acid, isobutoxybenzoic acid, nitrobenzoic acid, and resorcinbenzoic acid; aromatic polycarboxylic acids such as phthalic acid, nitrophthalic acid, and trimellitic acid; resin acids such as abietic acid, palustric acid, levopimaric acid, and dehydroabietic acid.

Suitable phenols include β-naphthol, o-nitrophenol, p-nitrophenol, catechol, resorcin, 4,4′-dihydroxydiphenyl-2,2-propane, phenol novolac, and cresol novolac.

Suitable reducing sugars include glucose, fructose, galactose, psicose, mannose, allose, tagatose, ribose, deoxyribose, xylose, arabinose, maltose, and lactose.

Suitable sulfides include allyl propyl trisulfide, benzyl methyl disulfide, bis(2-methyl-3-furyl) disulfide, dibenzyl disulfide, dicyclohexyl disulfide, difurfuryl disulfide, diisopropyl disulfide, 3,5-dimethyl-1,2,4-trithiolane, di-o-tolyl disulfide, dithienyl disulfide, methyl 2-methyl-3-furyl disulfide, methyl 2-oxopronyl disulfide, methyl 5-methylfurfuryl disulfide, methyl O-tolyl disulfide, methyl phenyl disulfide, methyl propyl trisulfide, 3-methylthio-butanal, 4-methylthio-butanal, 2-methylthio-butanal, phenyl disulfide, 4,7,7-trimethyl-6-thiabicyclo-[3.2.1]octane, 2,3,5-trithiohexane, 1,2,4-trithiolane, 2-(furfurylthio)-3-methylpyrazine, 2-(methylthio)benzo-thiazole, 2,8-epithio-p-menthane, 2-isopropyl-3-(methylthio)-pyrazine, 2-methyl-1,3-dithiolane, 2-(methylthio)acetal-dehyde, 2-methylthiolane, 2-methylthiothiazole, 3,5-diethyl-1,2,4-trithiolane, bis(2-methylbutyl) disulfide, diallyl trisulfide, dibutyl disulfide, diisobutyl disulfide, dipentyl disulfide, and di-sec-butyl disulfide.

Suitable thio ether phenols include 2,2-thiodiethylene-bis[3-(3,5-di-t-butyl-4-hydroxyphenyl)-propionate], 2,4-bis[(octylthio)methyl]-o-cresol, and 4,4-thiobis(2-t-butyl-5-methylphenol).

The fluxing agent used herein must be optimized for a particular curing agent used, while taking into account the shelf stability of the liquid epoxy resin composition and the fluxing capability retention thereof in the solder connecting temperature range. The fluxing agent should not volatilize or boil in the solder connecting temperature range so that it does not become a void source.

An appropriate amount of the fluxing agent compounded is 0.1 to 20 parts and more preferably 1 to 10 parts by weight per 100 parts by weight of epoxy resin (A) and curing agent (B) combined. Less than 0.1 pbw of the fluxing agent may fail to provide the desired fluxing performance whereas more than 20 pbw of the fluxing agent may cause a lowering of glass transition temperature, which leads to a loss of heat resistance and adhesion.

The fluxing agent may be compounded as such if it is liquid. If the fluxing agent is solid, it may be ground prior to compounding. However, depending on its amount, the fluxing agent in ground form can cause a noticeable viscosity buildup of the resin composition to impede the working operation tremendously. It is then desirable that the fluxing agent in ground form be previously melt mixed with the liquid epoxy resin or liquid curing agent. More desirably, the fluxing agent in ground form is previously melt mixed with the liquid epoxy resin or liquid curing agent at a temperature of 70 to 150° C. for 1 to 2 hours.

In addition to the aforementioned components, other components may be compounded in the epoxy resin composition of the invention, if necessary, as long as they do not adversely affect the benefits of the invention. Specifically, cure accelerators, stress reducing agents, surfactants, anti-foaming agents, leveling agents, ion trapping agents, pigments such as carbon black, dyes, and other additives are optionally compounded in the liquid epoxy resin composition of the invention.

The liquid epoxy resin composition of the invention may be prepared, for example, by agitating, dissolving, mixing, and dispersing the liquid epoxy resin, curing agent, inorganic filler, hygroscopic agent, optional fluxing agent, and optional additives simultaneously or separately while heating if necessary. The apparatus having mixing, agitating, dispersing and other functions is not particularly limited although apparatus equipped with agitating and heating units such as an automated mortar, three-roll mill, ball mill, and planetary mixer may be used alone or in a suitable combination.

The liquid epoxy resin composition of the invention, when used as an encapsulant, should preferably have a viscosity equal to or less than 1,000 Pa-s at 25° C., and more preferably equal to or less than 500 Pa-s at 25° C. The viscosity is measured by a cone-and-plate rotational viscometer according to JIS K-7117-2.

The composition may be molded by conventional techniques under ordinary conditions. Preferably, the molded composition is cured in a hot oven initially at 90 to 120° C. for at least 0.5 hour, then at 150 to 175° C. for at least 0.5 hour. If the time of initial heating at 90-120° C. is less than 0.5 hour, voids may generate after curing. If the time of subsequent heating at 150-175° C. is less than 0.5 hour, satisfactory cured properties may not be obtained. An appropriate curing time varies with the heating temperature.

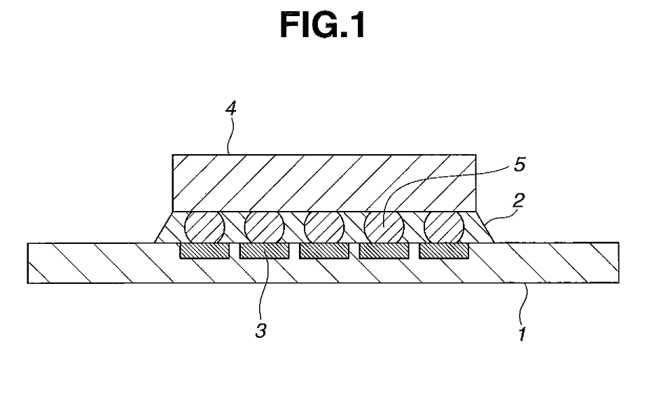

Referring to FIG. 1, one exemplary flip chip semiconductor device as used in the invention is illustrated. An organic substrate 1 has a circuit pattern surface including a plurality of pads 3. A semiconductor chip 4 having a plurality of solder bumps 5 is rested on the surface. The gap between organic substrate 1 and semiconductor chip 4 (or between bumps 5) is filled with an underfill material 2. The encapsulant embodied by the epoxy resin composition of the invention is effective when used as the underfill.

As to the mounting technique, a reflow technique can be used although the following technique is commonly employed. Using a flip chip bonder system, the semiconductor chip is positioned on the substrate coated with the liquid epoxy resin composition for no-flow underfill use and simultaneously heated and press bonded thereto. This technique performs solder bump connection and resin cure at the same time.

In this embodiment, the liquid epoxy resin composition for no-flow underfill use of the invention may be processed by the method described in the above-cited U.S. Pat. No. 5,128,746. For example, the epoxy resin composition of the invention is coated on a circuit substrate, a semiconductor chip carrying solder bumps thereon is positioned on the substrate, and the epoxy resin composition is heated for causing the solder bumps to reflow, thereby achieving connections to selected sites on the substrate and curing the epoxy resin composition.

When the liquid epoxy resin composition of the invention is used as an underfill material, the cured composition should preferably have a coefficient of expansion of 20 to 40 ppm/° C. at temperatures below the glass transition temperature.

### EXAMPLE

Examples of the invention are given below by way of illustration and not by way of limitation. Unless otherwise stated, all percents and parts are by weight.

### Examples 1 to 8 and Comparative Examples 1 to 3

Liquid epoxy resin compositions were prepared by combining an epoxy resin, a curing agent, spherical silica, a hygroscopic agent, a fluxing agent, a silicone-modified epoxy resin, a silane coupling agent, and carbon black in accordance with the recipe shown in Tables 1 and 2, intimately kneading the components on a planetary mixer, thoroughly mixing and dispersing on a three-roll mill, and deaerating the mixture in vacuum. Of the fluxing agents, L-glutamine was added in particulate solid form, and abietic acid was previously melt mixed with the liquid epoxy resin prior to mixing with the remaining components.

Tables 1 and 2 show the formulation of the liquid epoxy resin compositions of Examples and Comparative Examples. The values in Tables 1 and 2 are parts by weight (pbw).

TABLE 1

| | | Example | | | | | | | |
|---|---|---|---|---|---|---|---|---|---|
| Formulation (pbw) | | 1 | 2 | 3 | 4 | 5 | 6 | 7 | 8 |
| A | RE303S-L | 31.8 | 49.0 | 12.4 | 49.0 | 49.0 | 49.0 | 49.0 | 12.4 |
| | Epikote 630H | 31.8 | | | | | | | |
| | Epiclon HP4032D | | | 25.0 | | | | | 25.0 |
| B | Kayahard A-A | 33.0 | | | | | | | |
| | DAL-BPA | | 46.8 | | 46.8 | 46.8 | 46.8 | 46.8 | |
| | YH307 | | | 59.3 | | | | | 59.3 |
| C | Spherical silica | 100 | 100 | 100 | 70 | 50 | 100 | 50 | 100 |
| D | 4A powder | 10 | | 10 | | | | 5 | 15 |
| | 13X powder | | 10 | | | | 15 | | |
| | Goddball E-6C | | | | 50 | | | | |
| | ss3-150 | | | | | 100 | | 70 | |
| E | L-glutamine | 2 | | | | | | | |
| | Abietic acid | | | | | | 1.5 | 1.5 | 1.5 |

| | | | | | | | | |
|---|---|---|---|---|---|---|---|---|
| 2MZ-A-PW | | 0.2 | | 0.2 | 0.2 | 0.2 | 0.2 | |
| TPP-MK | | | 0.2 | | | | | 0.2 |
| Silicone-modified | 4 | 4 | 4 | 4 | 4 | 4 | 4 | 4 |
| epoxy resin | | | | | | | | |
| Silane coupling agent | 1 | 1 | 1 | 1 | 1 | 1 | 1 | 1 |
| Carbon black | 1 | 1 | 1 | 1 | 1 | 1 | 1 | 1 |

TABLE 2

| | | Comparative Example | | |
|---|---|---|---|---|
| Formulation (pbw) | | 1 | 2 | 3 |
| A | RE303S-L | 31.8 | 49.0 | 12.4 |
| | Epikote 630H | 31.8 | | |
| | Epiclon HP4032D | | | 25.0 |
| B | Kayahard A-A | 33.0 | | |
| | DAL-BPA | | 46.8 | |
| | YH307 | | | 59.3 |
| C | Spherical silica | 100 | 100 | 100 |
| D | 4A powder | | | |
| | 13X powder | | | |
| | Goddball E-6C | | | |
| | ss3-150 | | | |
| E | L-glutamine | 2 | | |
| | Abietic acid | | | |

| | | | |
|---|---|---|---|
| 2MZ-A-PW | | 0.2 | |
| TPP-MK | | | 0.2 |
| Silicone-modified epoxy resin | 4 | 4 | 4 |
| Silane coupling agent | 1 | 1 | 1 |
| Carbon black | 1 | 1 | 1 |

A. Liquid epoxy resin
Bisphenol F epoxy resin: RE303S-L (Nippon Kayaku Co., Ltd.,
epoxy equivalent 170)
Trifunctional epoxy resin of formula (1): Epikote 630H (Japan Epoxy
Resin Co., Ltd., epoxy equivalent 101)

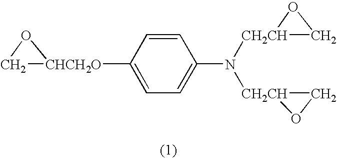

Naphthalene epoxy resin: Epiclon HP4032D (Dainippon Ink & Chemicals,
Inc., epoxy equivalent 150)
B. Curing agent
Aromatic amine curing agent: diethyldiaminodiphenylmethane (Nippon
Kayaku Co., Ltd., Kayahard A-A, amine equivalent 63.5)
Phenolic curing agent: diallylated bisphenol A (Honshu Chemical Co.,
Ltd., DAL-BPA, phenol equivalent 155)
Acid anhydride curing agent: a mixture of 3,4-dimethyl-6-(2-methyl-1-
propenyl)-1,2,3,4-tetrahydrophthalic anhydride and 1-isopropyl-4-methyl-
bicyclo[2.2.2]oct-5-ene-2,3-dicarboxylic anhydride (Japan Epoxy Resin
Co., Ltd., YH307, equivalent 234)
C. Inorganic filler
Spherical silica: spherical silica with an average particle size 2 μm and
a maximum particle size 10 μm (Tatsumori Co., Ltd.)
D. Hygroscopic agent
The following hygroscopic agents were used after drying in vacuum at
200° C. for 16 hours.
Molecular sieve: 4A powder (Union Showa Co., Ltd., average particle size
2 μm and maximum particle size 10 μm)
Molecular sieve: 13X powder (Union Showa Co., Ltd., average particle
size 5 μm and maximum particle size 25 μm)
Porous silica: Goddball E-6C (Suzuki Yushi Co., Ltd., average particle
size 2.5 μm, maximum particle size 15 μm, specific surface area 400
m²/g)
Porous silica: ss3-150 (MRC Unitec Co., Ltd., average particle size 3 μm,
maximum particle size 10 μm, specific surface area 150 m²/g)
E. Fluxing agent
Amino acid: L-glutamine (Aldrich Chemical Co.)
Organic acid: abietic acid (Acros Co.)
Other additives
Imidazole cure accelerator: 2MZ-A-PW (Shikoku Chemical Industry Co.,
Ltd.)
Phosphorus-based cure accelerator: TPP-MK (Hokko Chemical Industry
Co., Ltd.)
Stress reducing agent: silicone-modified epoxy resin = addition poly-
merized product of compound of formula (2) with compound of formula
(3) (weight average molecular weight 3,800, epoxy equivalent 291)

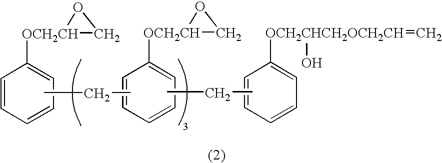

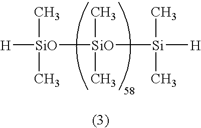

Carbon black: Denka Black (Denki Kagaku Kogyo K.K.)
Silane coupling agent: γ-glycidoxypropyltrimethoxy-silane (Shin-
Etsu Chemical Co., Ltd., KBM403)

The liquid epoxy resin compositions of Examples and Comparative Examples were evaluated by the following tests.

### (1) Viscosity

A viscosity (initial viscosity) of the resin composition was measured at 25° C. by a Brookfield rotational viscometer at a rotational speed of 4 rpm.

### (2) Shelf Stability

The resin composition was kept at 25° C. and 60% RH for 48 hours before it was measured for viscosity again under the same conditions as the initial. A percent change of the aged viscosity from the initial viscosity was computed, and a pot life was evaluated according to the following criterion.

| Rating | Percent viscosity change from the initial | Pot life |
|---|---|---|
| ◯ | <30% | Good |
| Δ | 30-100% | Fair |
| X | >100% | Short |

### (3) Solder Connection

There were furnished a flip chip type semiconductor chip and a substrate (4 areas/chip, 576 bumps/area, Sn-3.0Ag-0.5Cu solder). The resin composition was applied onto the substrate by means of a dispenser. Using a flip chip bonder system, the semiconductor chip was positioned on the substrate (solder bonding conditions: 260° C., 3 seconds under load 10N). The resin composition was then cured. Specifically for the amine curing agent systems, the composition was cured by heating at 120° C. for 0.5 hour and then at 165° C. for 3 hours. For the phenol and acid anhydride curing agent systems, the composition was cured by heating at 90° C. for 0.5 hour and then at 150° C. for 3 hours. In this way, flip chip semiconductor samples were prepared. For each resin composition, 10 samples were prepared (totaling to 40 areas). Solder connection was evaluated by examining conduction for each area.

### (4) Void

Using a ultrasonic flaw detector, the flip chip semiconductor samples prepared for the solder connection test were examined to count the number of chips in which voids generated in the resin, and to see a void generation situation.

| Rating | Void generation situation |
|---|---|
| ⊚ | No voids |
| ◯ | A few voids generated |
| Δ | Voids dispersed on entire surface |
| X | Numerous voids on entire surface |

### (5) Peel Test

Five samples selected from the void-free samples among the flip chip semiconductor samples were held at 30° C. and 65% RH for 192 hours. They were subjected to a reflow test by repeating five IR reflow cycles at a maximum temperature of 265° C., and then to a PCT test by holding under a PCT environment (121° C./2.1 atm) for 336 hours. After the reflow test and after the PCT test, the number of cracked or peeled chips was counted using a ultrasonic flaw detector.

### (6) Thermal Cycling Test

Five samples selected from the void-free samples among the flip chip semiconductor samples were held at 30° C. and 65% RH for 192 hours. They were subjected to a thermal cycling test, each cycle consisting of cooling at −65° C. for 30 minutes and heating at 150° C. for 30 minutes. After 250, 500, 750 and 1000 thermal cycles, the number of cracked or peeled chips was counted.

The test results are shown in Tables 3 and 4. In Comparative Examples, the peeling test and the thermal cycling test were omitted because no void-free samples were obtained. In Examples 4 and 5, additional void-free samples were prepared, on which the peeling test and the thermal cycling test were performed.

TABLE 3

| | | Example | | | | | | | |
|---|---|---|---|---|---|---|---|---|---|
| Test results | | 1 | 2 | 3 | 4 | 5 | 6 | 7 | 8 |
| Viscosity (Pa-s at 25° C.) | | 130 | 200 | 70 | 480 | 210 | 250 | 260 | 115 |
| Shelf stability | | ◯ | ◯ | ◯ | ◯ | ◯ | ◯ | ◯ | ◯ |
| Solder connection | | 35/40 | 37/40 | 35/40 | 39/40 | 38/40 | 36/40 | 38/40 | 36/40 |
| (Number of solder connected areas) | | | | | | | | | |
| Void | Void generating | ⊚ | ⊚ | ⊚ | ◯ | ◯ | ⊚ | ⊚ | ⊚ |
| | situation | | | | | | | | |
| | Number of void | 0/10 | 0/10 | 0/10 | 4/10 | 5/10 | 0/10 | 0/10 | 0/10 |
| | generated chips | | | | | | | | |
| Peel test | 5 IR reflow cycles | 0/5 | 0/5 | 0/5 | 0/5 | 0/5 | 0/5 | 0/5 | 0/5 |
| (number | at 265° C. | | | | | | | | |
| of peeled | PCT 336 hr | 0/5 | 0/5 | 0/5 | 0/5 | 0/5 | 0/5 | 0/5 | 0/5 |
| chips) | | | | | | | | | |
| Thermal | 250 cycles | 0/5 | 0/5 | 0/5 | 0/5 | 0/5 | 0/5 | 0/5 | 0/5 |
| cycling | 500 cycles | 0/5 | 0/5 | 0/5 | 0/5 | 0/5 | 0/5 | 0/5 | 0/5 |
| test | 750 cycles | 0/5 | 0/5 | 0/5 | 0/5 | 0/5 | 0/5 | 0/5 | 0/5 |
| (number of | 1000 cycles | 0/5 | 0/5 | 0/5 | 0/5 | 0/5 | 0/5 | 0/5 | 0/5 |
| defective | | | | | | | | | |
| chips) | | | | | | | | | |

TABLE 4

| | | Comparative | | |
|---|---|---|---|---|
| | | Example | | |
| Test results | | 1 | 2 | 3 |
| Viscosity (Pa-s at 25° C.) | | 60 | 110 | 30 |
| Shelf stability | | ◯ | ◯ | ◯ |
| Solder connection (Number of solder connected | | 39/40 | 40/40 | 39/40 |
| areas) | | | | |
| Void | Void generating situation | X | X | X |
| | Number of void generated chips | 10/10 | 10/10 | 10/10 |
| Peel test | 5 IR reflow cycles at 265° C. | — | — | — |
| (number of peeled | PCT 336 hr | — | — | — |
| chips) | | | | |
| Thermal cycling | 250 cycles | — | — | — |
| test (number | 500 cycles | — | — | — |
| of defective | 750 cycles | — | — | — |
| chips) | 1000 cycles | — | — | — |

As seen from Tables 3 and 4, the epoxy resin compositions of Examples are excellent in shelf stability and solder connection, fully effective for preventing void generation, and reliable. In contrast, the compositions having no hygroscopic agent incorporated in Comparative Examples 1 to 3 do not have a void inhibition effect, that is, numerous voids generate therein.

Japanese Patent Application No. 2007-118607 is incorporated herein by reference.

Although some preferred embodiments have been described, many modifications and variations may be made thereto in light of the above teachings. It is therefore to be understood that the invention may be practiced otherwise than as specifically described without departing from the scope of the appended claims.

1. A liquid epoxy resin composition for use as no-flow underfill comprising
(A) a liquid epoxy resin,
(B) a curing agent,
(C) an inorganic filler, and
(D) a hygroscopic agent.

2. The composition of claim 1, further comprising (E) a fluxing agent.

3. The composition of claim 1 wherein the hygroscopic agent (D) comprises a molecular sieve or a spherical porous silica having a specific surface area of 100 to 500 m²/g or both.

4. A liquid epoxy resin composition for the encapsulation of flip chip semiconductor devices, comprising the composition of claim 1.

5. A flip chip semiconductor device encapsulated with the liquid epoxy resin composition of claim 4 in the cured state.
